(19) United States
(12) Patent Application Publication
(10) Pub. No.: US 2024/0164016 A1
(43) Pub. Date: May 16, 2024

(54) SYSTEMS AND METHODS FOR ADDITIVE MANUFACTURING OF ELECTRONICS

(71) Applicants: Aviv Mordechai RONEN, Kibbutz Ein Carmel (IL); Oleg NAIGERTSIK, Haifa (IL)

(72) Inventors: Aviv Mordechai RONEN, Kibbutz Ein Carmel (IL); Oleg NAIGERTSIK, Haifa (IL)

(21) Appl. No.: 18/415,197

(22) Filed: Jan. 17, 2024

Related U.S. Application Data
(63) Continuation of application No. PCT/IL2022/050779, filed on Jul. 19, 2022.

(30) Foreign Application Priority Data
Jul. 19, 2021 (GB) GB2110382.5

(51) Int. Cl. H05K 1/09; H05K 3/12

(52) U.S. Cl. CPC H05K 1/092; H05K 3/125; H05K 3/1283; H05K 2203/013; H05K 2203/04; H05K 2203/095; H05K 2203/1131

(57) ABSTRACT

A method of manufacturing a printed wiring assembly “PWA” on a substrate, includes the following steps: receiving assembly data associated with said PWA; dispensing, onto said substrate, and in accordance with the assembly data, a conductive ink; curing the dispensed conductive ink; reducing, by plasma treatment, the cured conductive ink; depositing a solder material on top of at least a portion of the reduced conductive ink; picking and placing, in accordance with the assembly data, one or more components on the deposited solder material; and performing reflow soldering, by heating, of the deposited solder material, the one or more placed components, and the reduced conductive ink, forming an intermetallic compound therebetween.

### CROSS REFERENCE TO RELATED APPLICATIONS

This application is a continuation of PCT International Patent Application No. PCT/IL2022/050779, filed on Jul. 19, 2022, which claims priority from GB Patent Application No. GB2110382.5, filed on Jul. 19, 2021, which is incorporated herein by reference in its entirety.

### FIELD OF THE INVENTION

The present application is in the field of printed wiring assemblies (PWA) and additively manufactured electronics (AME).

### BACKGROUND OF THE INVENTION

In general, a printed wiring assembly (PWA) is a combination of a printed circuit board (PCB) with different components on top of it. It is important to emphasize the distinction that a PWA is a final product, whereas a PCB is only a part of the final product. Note that today, in the electronics industry as a rule, the physical connection between a PCB and the components is done by soldering processes. During a soldering process, a so-called “intermetallic compound” (IMC) is created. For example, during soldering, an intermetallic compound may be formed between copper (Cu) or nickel (Ni) from the PCB and tin (Sn) from the soldering material. The standards of the Institute for Interconnecting and Packaging Electronic Circuits (IPC) describe the production flow for both PCBs and PWAs, including all needed design, quality, and reliability requirements.

The world of additively manufactured electronics is divided into three principal segments: Firstly, ink manufacturers deal in so-called “conductive inks” (CI) which are mainly copper (Cu), nickel (Ni), and/or silver (Ag). Other conductive inks may include carbon (C) and/or gold (Au). There are also dielectric inks (DI), for which there are numerous compositions based on different polymers. Such dielectric inks can be cured by different approaches such as thermal and/or ultraviolet radiation techniques; secondly, machine vendors, who utilize the above-mentioned inks for different applications; and thirdly, a combination of the two—these types of vendors ordinarily utilize their own manufactured inks alongside proprietary equipment.

Embodiments of the present invention are intended to bridge between PWA manufacturing and AME approaches, which the Inventors believe represents the future of PWA in the world. Implementation of this technology of the component level assembly is possible as well.

The problem with current AME approaches can be divided into two separate sub-problems:
(i). AME based on silver (Ag) conductive ink—silver does not make a reliable IMC with tin (Sn), see detailed explanation below based on IPC-AJ-820A, IPC-4553A, IPC-1602, IPC-7094A, IPC-CH-65H and IPC-D-279 accordingly; and
(ii). AME based on copper conductive ink—copper oxidizes quickly, hence it is impossible to solder it using current processing sequences.

According to IPC-AJ-820A, 4.6.5 Immersion Silver, immersion silver (IAg) is a viable solderable surface finish for all categories of printed boards. The surface is coplanar and is compatible with eutectic and lead-free solders. It may be the preferred finish for very high frequency RF applications because it avoids the skin effect problem that may arise with nickel-gold finishes. The immersion silver coating consists of pure silver and a small amount of organic additives. At assembly, the silver is dissolved in the solder and a SnxCuy or SnxNiy IMC is formed accordingly. Once properly formed, these IMCs are reliable and well known in the industry. As this surface finish has established itself in the marketplace, its advantages and weaknesses have become better understood. Instances of interfacial voiding reported by early users have been resolved Immersion silver is susceptible to creep corrosion in humid environments that contain sulfur compounds. Solder mask defined lands are more susceptible to creep corrosion, as compared to pattern defined lands. See also the IPC immersion silver specification (IPC-4553).

The advantages and limitations of Immersion Silver Surface Finish are outlined in IPC-AJ-820A, Table 4-9, which lists as advantages: uniform coplanar surface; excellent wettability, with eutectic and lead-free solder; and low loss finish compatible with RF design requirements. However, IPC-AJ-820A, Table 4-9, also lists as limitations limited re-workability at the bare printed board level; solder mark/must be fully cured before immersion silver; reduced shelf life in environments containing sulfur compounds or chlorides; excessive thickness of IAg combined with lead-free silver bearing solder has the potential to create an embrittled solder joint; and no nickel barrier allows copper dissolution during lead-free solder assembly and/or rework.

According to IPC-AJ-820A, 7.11.2 General Guidelines for Migrating to RoHS Compliant Finishes, C. Finishes that Should Generally be Avoided, 9. Silver, silver finishes are not prone to whisker growth in most environments. However, rapid growth of silver dendrites or, in some cases, silver whiskers, may form in the presence of H2S (found in some cases where the environmental air pollution contains SO2). Additionally, users sometimes avoid silver finishes due to potential issues with electromigration and solderability shelf life.

According to IPC-AJ-820A, 8.9.1.2 Attachment Issues, when surface mounting, good solderability is essential for high assembly yield. The solderability of the terminations should be tested on all new components upon receipt and after any prolonged storage (longer than one month). Bare silver-palladium terminations should be avoided because such terminations tend to lose solderability. Component terminations should have a diffusion barrier layer (typically nickel or copper) under the solder to prevent the leaching of silver from the underlying silver-palladium termination. No silver should be detectable on the surface of the component. Conductors can be connected to land at any portion of the land perimeter, but unfilled vias should not be located on, or in contact with, the land. When reflow soldering is used, conductors should be covered with solder resist to minimize scavenging of solder away from the component termination. This is especially important when conductors connect to plated-through holes near the component termination land.

According to IPC-D-279, 5.4 Component Termination Finishes, because the silver content is easily and rapidly dissolved or leached into molten solder, the soldering process window is tightly constrained as to temperature range and peak temperature duration. A high silver content in the solder joint results in loss of ductility.

According to IPC-D-279, 5.4.4 Gold, Palladium, Silver Termination Finishes, silver requires care in handling and storage to avoid tarnishing which can interfere with solderability.

According to IPC-D-279, 5.5 Solderability of Termination Finishes, tarnished finishes may be difficult to solder and result from the reaction of a silver termination finish with sulfur compounds which may be emitted by chemical processes using sulfur or storage containers made from paper containing residual sulfur compounds. Silver-plated terminations should be stored with an oxidation inhibitor.

According to IPC-D-279, 5.10 Components to Avoid or to Use with Caution, the standard mentions: components with thick silver or gold plating or paste as the solderable termination; and aluminum electrolytics with silver anode.

According to IPC-D-279, F-7.4 Variable Resistors, if halogenated solvents, activated fluxes or saponifiers leak past the seal, enter the component cavity, dissociate and are then exposed to moisture, one result is lowered insulation resistance. If there is electrical bias present, migration of the thick film electrodes (generally of silver) and shorting has been observed. Metal migration tracks (dendrites) are very fragile; the “short” can disappear with minimum mechanical movements and may be noted as an “NTF” (Negative Temperature Coefficient). A change in flux application method on a wave soldering machine was found to be responsible for the ingress of flux into a sealed pot. Silver dendrite growth has been observed inside potentiometers due to intrusion of high-pressure wash water past improper, cracked or heat-distorted seals.

According to IPC-D-279, F-8.1 Multilayer Ceramic Chip Capacitors Caution, shorts occur due to silver electrode metal and end termination metallization migration under temperature/humidity/bias stress, and the commonly used plastic coating is not a reliable replacement for the original ceramic layers and silver migration is likely.

According to IPC-D-279, F-11.2.1 Batteries, the silver-plated contact materials may lead to dendriting with moist corrosive environments in combination with low powered circuits, if the elastomer does not form a gas-tight seal.

According to IPC-D-279, F-12.3 Solder Joints, solder joints to terminations finishes containing silver joints to components can fail immediately if the terminations are manufactured with a final terminal finish of silver paste or palladium-silver paste; these materials rapidly leach into molten lead-tin solder and the resulting joint is weak.

According to IPC-D-279, L-6.0 Corrosion Design Checklist, avoid exposed silver plating, silver pastes, and silver adhesives; over plate silver conductor material with nickel or conformally coat or locate the component so that water will not condense and run onto the silver. Includes MLCC (Multi Level Chip Capacitor), DIP (Dual In-line Package), rotary and slide switch, variable resistor, and buzzer packages.

According to IPC-CH-65B, 7 Contamination And Its Effects On PWBS, 7.1.2 Background, the long-term effects of no-clean processing on reliability of printed circuit boards continues to be a source of concern, especially when coupled with reductions in lead pitch and conductor spacing. Further reliability risks are introduced with the transition to lead-free solder technology, since these alloys typically include silver and are processed at higher temperatures than eutectic tin-lead solder.

According to IPC-CH-65B, 7.5 Creep Corrosion, creep corrosion is an increasing phenomenon on printed circuit boards present in environments that contain abnormal levels of sulfur or other pollutant gasses. Elemental sulfur is regulated by OSHA (Occupational Safety and Health Administration) as a nuisance dust and is allowed in a human working environment at part per million (ppm) levels. Sulfur in ppm levels can cause computer systems to fail within 2 months of use. Planar board finishes, such as immersion silver and organic solder preservative (OSP) over copper, are especially susceptible to this type of corrosion. Creep corrosion does not require an electrical potential to occur making is subtly different from electrochemical migration. Creep corrosion can occur on any surface finish. Similar to electrochemical migration, creep corrosion requires a source of contamination and moisture. Creep differs from ECM (Electro Chemical Migration) in that the corrosion does not require an electrical field, but occurs from airborne contaminants, particularly sulfur. If a circuit board is exposed to humid environments rich in airborne contamination containing sulfur, creep corrosion will occur. Sulfur based airborne contaminants react with silver and copper to form silver and copper sulfides. These contaminants grow in all directions equally. Creep corrosion can cause electrical opens in very fine line circuitry, as well as the creation of electrical shorts when the corrosion creeps across conductors. Corrosion failure rates raise when three factors intersect: increased airborne pollutants, reduced circuit protection, and miniaturization. The severity of the problem is due to less robust materials and more interaction opportunities. In this extreme corrosion mechanism, the surface finish is corroded. The corrosive ions form copper salts. Monolayers of water can carry the conductive salts across conductors. With heat generation, the electrolyte dries, leaving behind a crystallized salt. If more humidity comes in contact with circuitry, the cycle repeats, with the formation of rings of crystalline deposits.

According to IPC-CH-65B, 7.5.2 Creep Corrosion and PCB Board Finish, immersion silver finishes are becoming the standard PCB finish in the electronics industry. With the change to immersion silver board finishes, PCB failures relating to sulfur airborne contamination levels have increased.

According to IPC-CH-65B, 7.5.3 Creep Corrosion and Circuit Board Cleanliness, on assemblies with exposed silver, severe corrosion occurred over time, but the corrosion was not considered creep corrosion. In boundary areas where silver was exposed to flux residues, severe creep corrosion occurred. The flux residues exposed to the silver boundary areas promoted silver corrosion that migrated onto the solder mask surface. Also, PCB storage locations are critical to sulfur induced tarnishing, especially of silver or high-silver finishes. PCB storage adjacent to the cafeteria where eggs were often served resulted in sulfur-based tarnishing. Industrial control electronics in a Vidalia onion processing plant experienced severe corrosion as Vidalia onions contain very high levels of sulfur.

According to IPC-AJ-820A, 7.11.7 Printed Circuit Boards (PCB), the surface finish on PCB lands (made of copper) are designed to protect the base metal against oxidation that could result in poor solder joints during assembly operations. HASL (Hot Air Solder Leveled) tin-lead finishes have been the coating of choice for most of the last fifty years. To comply with legislation, alternative Pb-free surface finishes must be considered. These finishes include organic solder preservatives, immersion gold over electroless nickel, electroplated gold over electroplated nickel, Pb-free HASL, immersion silver, and immersion tin. Of these surface finishes, immersion tin is susceptible to the formation of pure tin whiskers and immersion silver is susceptible to the formation of silver sulfide dendrites. Both tin whiskers and silver sulfide dendrites can create electrical shorts; however, the formation mechanisms and the required environmental conditions are different. There have been no reported instances of tin whiskers on SnCu HASL finished PCBs. However, it should be noted that the use of SnCu HASL as a board finish has been very limited. For all of these finishes, individual processes vary tremendously relative to film quality, corrosion resistance, shelf life, etc., and the user should work closely with the process provider to evaluate each particular process. Aside from whisker and dendrite growth, other aspects of the surface finishes will affect selection, including cost, shelf life, solderability, manufacturability, corrosion resistance, and technical limitations with certain assembly processes, component types, and board designs.

According to IPC-4553A, 1.1 Statement of Scope, the specification sets the requirements for the use of Immersion Silver as a surface finish for printed boards. The specification is intended to set requirements for IAg deposit thickness based on performance criteria. It is intended for use by chemical suppliers, printed board manufacturers, electronics manufacturing services (EMS) and original equipment manufacturers (OEM).

According to IPC-4553A, 1.2 Description, IAg is a thin immersion deposit over copper. It is a multifunctional surface finish, applicable to soldering. It may also be applicable for some press fit connections and as a contact surface. It has the potential to be suitable for aluminum wire bonding. The immersion silver protects the underlying copper from oxidation over its intended shelf life. Exposure to moisture and air contaminants, such as sulfur and chlorine, may negatively impact the useful life of the deposit. The impact can range from a slight discoloration of the deposit to the pads turning completely black. Proper packaging is a requirement.

According to IPC-4553A, 1.3 Objective, the specification sets the requirements specific to IAg as a surface finish. As other finishes require specifications, they are addressed by the IPC Plating Processes Subcommittee as part of the IPC-4550 specification family.

According to IPC-4553A, 1.4 Performance Functions, 1.4.1 Solderability, the primary function of IAg is to provide a solderable surface finish, suitable for all surface mount and through-hole assembly applications and with an appropriate shelf life. The deposit has demonstrated the ability to meet a shelf life of 12 months per IPC J-STD-003 and industry data, when handled per the specification's requirements.

According to IPC-4553A, 3.2.1 Immersion Silver (IAg) Thickness, an upper limit for immersion silver thickness has been established. The minimum immersion silver thickness shall be 0.12 μm minimum and the maximum thickness shall be 0.4 μm. The typical value ranges from 0.2.1.tm to 0.3 μm.

According to IPC-4553A, Packing and Handling Requirements immersion silver boards should be packaged as soon as possible, to prevent exposure to chlorides and sulfides in the air; use sulfur free, pH neutral paper to wrap stacks of parts and then plastic wrap. Storage should be in sealed bags or sealed containers to eliminate direct contact with air; wrapped packages should be stored below 30° C. (86° F.) and 75% R.H; avoid using desiccant in the packages as desiccant can contain/absorb sulfur compounds; adhesive tape, adhesive labels, stamps, markers and rubber bands shall not be used in silver plated printed board applications or inside the exterior, sealed plastic bags or containers of such boards, even if the interior packaging is done with sulfur-free paper as all of these tapes, labels, stamps, markers and rubber bands contain sulfur bearing compounds that will tarnish the silver coating; marking or labeling of each package shall only be done on the exterior/outside of the final, sealed plastic bags or containers; and if the original package is opened and not all of the boards consumed at the EMS/OEM, they should be rewrapped as soon as possible and returned to a storage condition, preferably not-to-exceed 30° C. (86° F.) and 75% R.H.

According to IPC-1602, 3.4.1.4 Effects on Immersion Silver Finishes, during baking, silver tarnish will form if sulfur or chlorine are present in the air or contaminating the bake oven. Tarnish becomes visible when it grows to approximately 5 nm in thickness but does not degrade solderability until it reaches about 50 nm. If tarnish is visible after baking, solderability should be verified. IPC-1602, Table 3-1 also indicates silver may tarnish.

According to IPC-1602, 4.1.3.3 Immersion Silver, immersion silver solderability is mostly unaffected by exposure to oxygen. However, chlorine and sulfur compounds have a strong affinity for immersion silver causing significant solderability degradation. Packaging for immersion silver final finishes should prevent exposure to atmospheric contaminates and humidity. Sulfur absorbent, pH neutral material (e.g. Silver Saver® paper) is often included in packaging.

According to IPC-1602, 4.2.6 Immersion Silver Printed Boards, printed boards with Immersion Silver as the final finish shall be covered with protective sulfur-absorbing paper (e.g. Silver Saver® paper) inside the MBB (Moisture Barrier Bag). Any separation sheets placed between boards shall be sulfur free and pH neutral, or sulfur absorbing paper (treated on both sides). See IPC-4553 for additional information.

According to IPC-1602, Example 2: Possible Special Requirements, special requirements may apply for printed board designs that are especially fragile, sensitive to environmental conditions, high cost, or must be stored between 12-24 months. For printed boards with immersion silver finish, a sheet of corrosion protection paper shall cover each silver surface.

Due to these principal limitations, it is impossible to utilize current AME approaches in order to produce PWA according to IPC standards. PWAs in accordance with IPC standards comprise well known, reliable intermetallic compounds with characteristic properties useful for large scale, uniform quality assurance. Hence, current approaches are in fact limited to PCB production only, and as previously noted, a PCB itself is not a whole product (e.g. a device) but only the infrastructure for PWA which is itself a whole product. Only the whole product has an added value to the customer, and so in overcoming this significant and principal hurdle the Inventors are opening the door for the mass usage of AME which is otherwise virtually impossible or significantly limited at current.

### SUMMARY OF THE INVENTION

One aspect of the present invention provides a method of manufacturing a printed wiring assembly “PWA” on a substrate, said method comprising: receiving assembly data associated with said PWA; dispensing, onto said substrate, and in accordance with the assembly data, a conductive ink; curing the dispensed conductive ink; coating cured conductive ink by using OSP, preferably according to IPC 4555, or reducing, by plasma treatment, the cured conductive ink; depositing a solder material on top of at least a portion of the reduced conductive ink; picking and placing, in accordance with the assembly data, one or more components on the deposited solder material; and performing reflow soldering, by heating, of the deposited solder material, the one or more placed components, and the reduced conductive ink, forming an intermetallic compound therebetween.

In some embodiments the plasma treatment comprises hydrogen plasma or any other mixture of gasses regardless of plasma process which can successfully reduce the surface of the conductive ink.

Another aspect of the invention provides a method of manufacturing a printed wiring assembly “PWA” on a substrate, said method comprising: receiving assembly data associated with said PWA; dispensing, onto said substrate, and in accordance with the assembly data, a conductive ink “CI”; dispensing, onto the dispensed conductive ink, and in accordance with the assembly data, a thin film of silver; co-curing the dispensed conductive ink and dispensed silver, forming a silver over CI finish; depositing a solder material on top of at least a portion of the silver over CI finish; picking and placing, in accordance with the assembly data, one or more components on the deposited solder material; and performing reflow soldering, by heating, of the deposited solder material, the one or more placed components, and the silver over CI finish, forming an intermetallic compound therebetween.

In some embodiments, as required per IPC standards, the target thickness of dispensed silver is between 0.12 μm and 0.4 μm, but not limited to this interval.

In some embodiments co-curing the dispensed conductive ink and the dispensed silver comprises at least one of sintering, thermal decomposition, or thermal coupling of the dispensed conductive ink and the dispensed silver, at the same time.

Another aspect of the invention provides a method of manufacturing a printed wiring assembly “PWA” on a substrate, said method comprising: receiving assembly data associated with said PWA; dispensing, onto said substrate, and in accordance with the assembly data, a conductive ink; depositing, soon thereafter, a solder material on top of at least a portion of the dispensed conductive ink, wherein the dispensed conductive ink has been at most partially cured prior to depositing said solder material soon thereafter; picking and placing, in accordance with the assembly data, one or more components on the deposited solder material; and performing reflow soldering, by heating, of the deposited solder material, the one or more placed components, and the dispensed conductive ink, forming an intermetallic compound therebetween.

In some embodiments curing the dispensed conductive ink comprises at least one of: sintering, thermal decomposition, or thermal coupling of the dispensed conductive ink.

In some embodiments the conductive ink comprises at least one of copper or nickel.

In some embodiments performing reflow soldering comprises preferably any of the three reflow profiles as mentioned in IPC-7095D, Table 7-7, or equivalent. In any case, the rule of reflow profile establishing is T melt of any alloy per IPC-006 plus approximately 25° C. as a peak temperature.

In some embodiments dispensing a conductive ink comprises: dispensing a first conductive ink comprising copper; dispensing a second conductive ink comprising nickel on top of the dispensed first conductive ink comprising copper; and coupling, by heating, the first conductive ink comprising copper and the second conductive ink comprising nickel, forming a nickel over copper intermetallic compound therebetween.

Another aspect of the invention provides a printed wiring assembly printed on a substrate according to the method of any preceding embodiment.

Another aspect of the invention provides a system for manufacturing a printed wiring assembly “PWA” on a substrate, said system comprising: at least one processor, configured to receive assembly data associated with said PWA; at least one positioning system; a plurality of dispensing units; at least one energy source; and at least one pick and place “P&P” unit, wherein at least one of the plurality of dispensing units is configured to dispense a conductive ink, according to the assembly data, wherein the at least one energy source is configured to cure the dispensed conductive ink, and wherein the at least one energy source is configured to reduce, by plasma treatment, the cured conductive ink, wherein at least one of the plurality of dispensing units, or the at least one P&P unit, is configured to deposit a solder material on top of at least a portion of the reduced conductive ink, wherein the at least one P&P unit is configured to pick and place one or more components on the deposited solder material, according to the assembly data, wherein the at least one energy source is configured to perform reflow soldering of the deposited solder material, the one or more placed components, and the reduced conductive ink, forming an intermetallic compound therebetween, and wherein the at least one positioning system is configured to control a position and orientation of at least one of: the substrate; one or more dispensing units of the plurality of dispensing units; the at least one energy source; and/or the at least one P&P unit.

Another aspect of the invention provides a system for manufacturing a printed wiring assembly “PWA” on a substrate, said system comprising: at least one processor, configured to receive assembly data associated with said PWA; at least one positioning system; a plurality of dispensing units; at least one energy source; and at least one pick and place “P&P” unit, wherein at least one of the plurality of dispensing units is configured to dispense a conductive ink “CI”, according to the assembly data, wherein at least one of the plurality of dispensing units is configured to dispense a thin film of silver onto the dispensed conductive ink, according to the assembly data, wherein the at least one energy source is configured to co-cure the dispensed conductive ink and the dispensed silver, forming a silver over CI finish, wherein at least one of the plurality of dispensing units, or the at least one P&P unit, is configured to deposit a solder material on top of at least a portion of the silver over CI finish, wherein the at least one P&P unit is configured to pick and place one or more components on the deposited solder material, according to the assembly data, wherein the at least one energy source is configured to perform reflow soldering of the deposited solder material, the one or more placed components, and the silver over CI finish, forming an intermetallic compound therebetween, and wherein the at least one positioning system controls a position and orientation of at least one of: the substrate; one or more dispensing units of the plurality of dispensing units; the at least one energy source; and/or the at least one P&P unit.

Another aspect of the invention provides a system for manufacturing a printed wiring assembly “PWA” on a substrate, said system comprising: at least one processor, configured to receive assembly data associated with said PWA; at least one positioning system; a plurality of dispensing units; at least one energy source; and at least one pick and place “P&P” unit, wherein at least one of the plurality of dispensing units is configured to dispense a conductive ink, according to the assembly data, wherein at least one of the plurality of dispensing units, or the at least one P&P unit, is configured to deposit a solder material on top of at least a portion of dispensed conductive ink soon thereafter, wherein the dispensed conductive ink has been at most partially cured prior to depositing said solder material soon thereafter, wherein the at least one P&P unit is configured to pick and place one or more components on the deposited solder material, according to the assembly data, wherein the at least one energy source is configured to perform reflow soldering of the deposited solder material, the one or more placed components, and the dispensed conductive ink, forming an intermetallic compound therebetween, and wherein the at least one positioning system controls a position and orientation of at least one of: the substrate; one or more dispensing units of the plurality of dispensing units; the at least one energy source; and/or the at least one P&P unit.

In some embodiments the conductive ink comprises at least one of copper or nickel.

In some embodiments at least one of the plurality of dispensing units can dispense at at least one of: any predefined angle, and/or any dynamically changing angle.

In some embodiments at least one of the plurality of dispensing units is configured to deposit solder material by dispensing solder paste.

In some embodiments the at least one P&P unit is configured to deposit solder material by picking and placing a solder material preform on at least a portion of a dispensed conductive ink.

In some embodiments the at least one P&P unit is any of: a tray loading type; a reel loading type; or a bulk loading type.

In some embodiments there is further provided at least one flipper for rotating the substrate.

In some embodiments the system is configured for gas purging.

In some embodiments the system comprises an atmosphere of gas, or mixture of gases, other than oxygen.

In some embodiments the system comprises a gas or mixture of gases suitable for at least one of: creating a surface reducing atmosphere, and/or creating an inert atmosphere.

In some embodiments the system further comprises at least one automatic optical inspection “AOI” unit.

In some embodiments the AOI unit comprises backlight illumination.

In some embodiments the system further comprises at least one fume chamber.

In some embodiments the system comprises at least one moveable pedestal controllable by the at least one positioning system.

In some embodiments the at least one moving pedestal comprises thermal control.

In some embodiments the system further comprises at least one of: a failure modes and effects analysis “FMEA” module; and/or a statistical process control “SPC” module.

In some embodiments the at least one energy source is one of: convection based; infrared radiation based; or laser based.

In some embodiments the at least one energy source is configured to perform any of: curing, plasma generation, and/or solder material reflow.

In some embodiments the substrate is manufactured by dispensing a dielectric ink from at least one of the plurality of dispensing units.

In some embodiments the system further comprises at least one of: a solder ball or solder bump dispensing unit; a wire bond, ball bonding, and/or wedge bonding unit; conductive adhesive dispensing; an anisotropic conductive film “ACF” placement unit; an under fill dispensing unit; dam and fill dispensing; glop top dispensing; a conformal coating unit; a marking unit based on additive or subtractive approaches; functional plasma treatment of any of the above mentioned processes; metrological and inspection techniques based on non-destructive testing “NDT” comprising at least one of: X-Ray, mechanical dimension optical inspection, and flying probe electrical test; and/or a grinder unit for planarization and polishing of cured ink layers.

In some embodiments the system is implemented for component level assembly and/or Heterogeneous Integration “HI” approaches.

### BRIEF DESCRIPTION OF THE DRAWINGS

The subject matter regarded as the invention is particularly pointed out and distinctly claimed in the concluding portion of the specification. The invention, however, both as to organization and method of operation, together with objects, features, and advantages thereof, may best be understood by reference to the following detailed description when read with the accompanying drawings in which:

FIG. 1 is a table showing intermetallic compounds and diffusion constants for near-eutectic SnPb solders, based on IPC-AJ-820, Table 9-1;

FIG. 2 is a table showing recommendations for printed board baking profiles, based on IPC-1602, Table 3-1.

FIG. 3 is a thermal profile schematic, based on IPC-7530A, FIG. 3-1;

FIG. 4 is a block diagram of a system according to embodiments of the invention;

FIG. 5A is a method flowchart, according to embodiments of the invention;

FIG. 5B is a schematic diagram showing additive printing of layers, according to embodiments of the invention;

FIG. 6A is a method flowchart, according to embodiments of the invention;

FIG. 6B is a schematic diagram showing additive printing of layers, according to embodiments of the invention;

FIG. 7A is a method flowchart, according to embodiments of the invention;

FIG. 7B is a schematic diagram showing additive printing of layers, according to embodiments of the invention; and

FIG. 8 is a high-level block diagram showing assembly of a PWA, according to embodiments of the invention.

Where appropriate, reference numerals which relate to the same or equivalent features have been repeated across figures.

### DETAILED DESCRIPTION OF THE INVENTION

In the following description, various aspects of the present invention will be described. For purposes of explanation, specific configurations and details are set forth in order to provide a thorough understanding of the present invention. However, it will also be apparent to one skilled in the art that the present invention may be practiced without the specific details presented herein. Furthermore, well known features may be omitted or simplified in order not to obscure the present invention.

Before at least one embodiment is described the following terms are used in line with IPC standards:

According to IPC-7094A, 10.8.1 Solder Joints and Attachment Types, a solder joint consists of several different materials, many of which are only superficially characterized. A solder joint consists of: the base metal at the printed board; one or more intermetallic compounds; a layer from which the solder constituent forming the board-side IMC(s) has been depleted; solder grain structure, which consists of at least two phases containing different proportions of the solder constituents, as well as any deliberate or inadvertent contaminations; a layer from which the solder constituent forming the component-side IMC(s) has been depleted; one or more IMC layers of a solder constituent with the component base metal; and base metal at the component.

According to IPC-7095D, 8.3 Solder Joints and Attachment Types, a solder joint consists of several different materials, many of which are only superficially characterized. A solder joint consists of: base metal at the printed board; one or more IMCs; bulk solder; a layer from which the solder constituent forming the component-side IMC(s) has been depleted; one or more IMC layers of a solder constituent with the component base metal; and base metal at the component.

According to IPC-9701A, 3 Terms, Definitions and Concepts, 3.1 General, during use, surface mount solder attachments can be subjected to a variety of loading conditions which can lead to premature failure. The underlying assumption is that the solder joints have been properly wetted, forming a good metallurgical bond between the solder and the base metal of the component build and Printed Wiring (Circuit) Board (PWB/PCB). This assures that early failures are not infant mortalities due to defective solder joints.

According to IPC-AJ-820, 6.2 Inherent Solderability, it is recognized that all practical soldering operations involve the formation of an intermetallic compound or compounds. An IMC is developed at the interface between the solder and the surfaces joined. The presence of the IMCs at the interface lowers the system energy, eases, and speeds solder spreading. Therefore, the inherent solderability of a surface tends to reflect the kinetics with which the surface forms an IMC (typically with copper or nickel). It is also normal that some delay will occur before soldering is actually attempted. Even components for a Just In Time (JIT) manufacturing process may have been stored for some time at the supplier's location. A clean surface may be subject to oxidation or corrosive attack during this storage period. Thus, a common practice is to protect this surface with a more robust solderable finish so that a complete cleaning is not required prior to soldering.

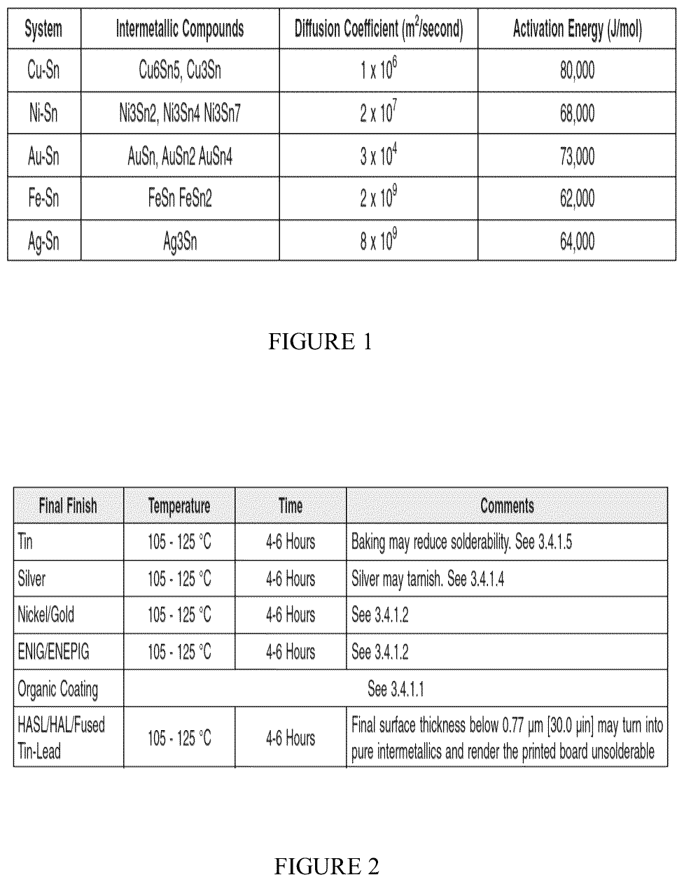

FIG. 1, which is based on IPC-AJ-820 Table 9-1, shows intermetallic compounds and diffusion constants for near-eutectic SnPb solders.

According to IPC-7530A, 1 Scope, the standard describes thermal profile guidelines and practical guidelines to meet requirements to produce acceptable solder joints in mass soldering processes, including but not limited to reflow and wave soldering. Thermal profile is a unique temperature vs. time plot for each fully populated printed wiring board assembly (PWBA), using thermocouples attached with high-temperature solder or copper or aluminum tapes to selected representative components of the PWBA as it travels at a given belt speed (i.e. transport speed) through various temperature zones of an oven or soldering system.

According to IPC-7530A, 1.1 Purpose, the purpose of the standard is to provide useful and practical information for developing thermal profiles to produce acceptable SnPb and Pb-free electronics assemblies.

According to IPC-7530A, 1.2 Background, during mass soldering it is important that all solder joints reach the minimum soldering temperature Minimum soldering temperature is the minimum temperature necessary to ensure metallurgical bonding of the solder alloy and the base metals to be soldered. Metallurgical bonding requires that the surfaces to be soldered and the solder reach this minimum soldering temperature for a sufficient time to allow wetting of the solder surfaces and the formation of a layer(s) of intermetallic compound(s) of some of the base metal(s) with one or more constituents of the solder alloy. As a practical matter, minimum soldering temperature is somewhat (— 25° C.) above the liquidus temperature of the solder alloy. The solder joint on a given PWBA that is the last to reach minimum soldering temperature (typically on or underneath one of the components with the highest thermal mass) determines the temperature profile setting for a given PWBA and soldering process/machine. Developing a good profile is a balancing act for the process engineer, who also needs to make sure smaller and temperature-sensitive components do not overheat or become damaged. Reflow soldering requires controlled rates of heating and subsequent cooling; however, too rapid a heating rate can damage PWBAs and components. High cooling rates can also damage components and result in temperature gradients of sufficient magnitude to warp PWBAs and larger components and also fracture solder joints. Because of this, appropriate temperature profiling is essential for ensuring high-quality solder joints.

FIG. 2, which is based on IPC-1602, Table 3-1, is a table showing recommendations for printed board baking profiles.

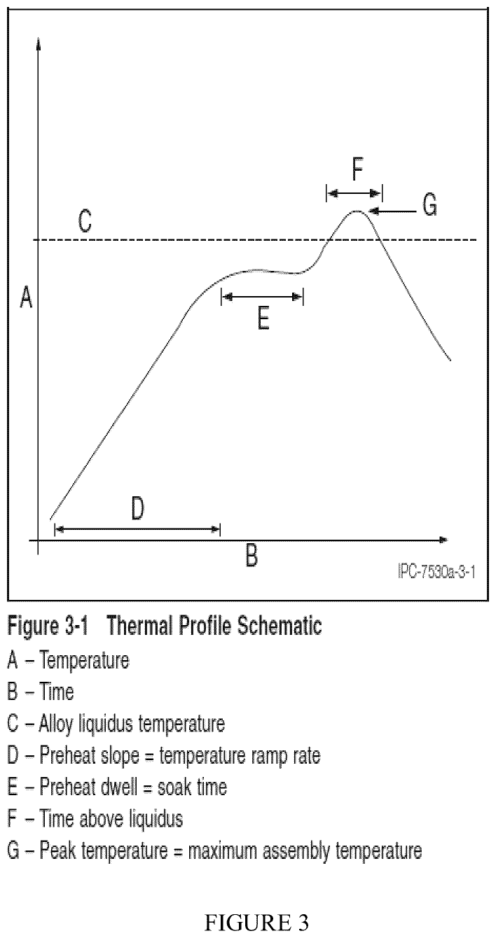

FIG. 3, which is based on IPC-7530A, FIG. 3-1, shows a thermal profile schematic, in which: axis A is temperature; axis B is time; C is the alloy liquidus temperature; D is the preheat slope which is equal to the temperature ramp rate; E is the preheat dwell which is equal to the soak time; F is the time above liquidus; and G is the peak temperature which is equal to the maximum assembly temperature.

According to a broad aspect, the invention provides a solution that bridges between the two approaches of additively manufactured electronics and printed wiring assemblies. In order to solder inherently, literally with a formation of a well-known IMCs, a new AME machine according to embodiments of the invention is equipped with: all AME standard features including ink dispensing and curing methods; an extra dispenser for soldering material, preferably based on SnPb and/or SnAgCu metallurgies; extra Pick & Place features for component mounting on top of the PCB; and extra reflow features for soldering the components according to well established reflow profiles. The conductive ink may be based mainly on copper (Cu) or nickel (Ni) with or without final finish.

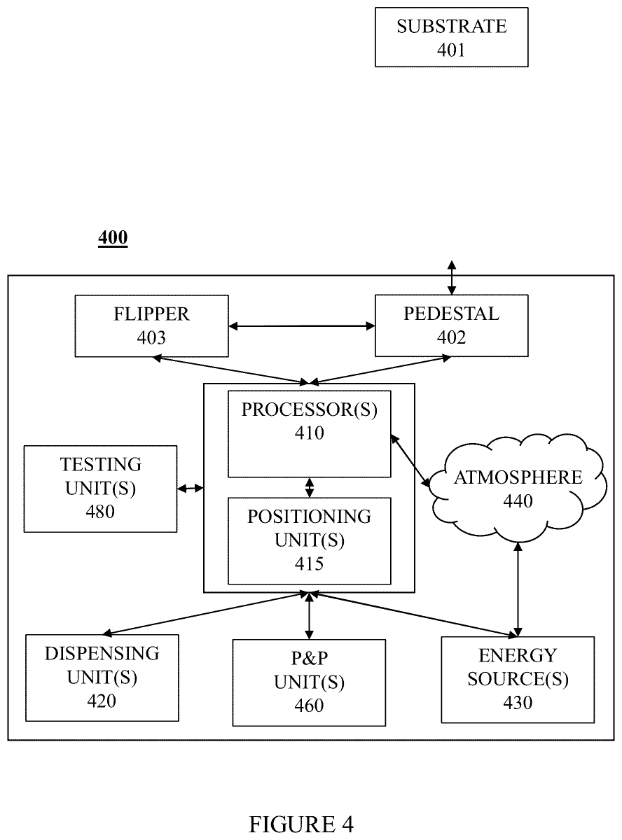

In accordance with an embodiment of the invention, and with reference to FIG. 4, there is thus provided a system 400 for printed wiring assembly, e.g. for assembly of PWAs by AME techniques. The system may produce a PWA on a substrate 401 such as a PCB. Substrate 401 may be received or may be initially manufactured by system 400 by dispensing dielectric inks using methods known in the art. System 400 may be provided as one machine or as a cluster of multiple interconnected machines.

System 400 comprises at least one processor 410. Processor 410 may be configured to receive assembly data. The assembly data may comprise a Bill of Material (BoM) which may comprise a list of components. The assembly data may comprise machine readable code in a computer numerical control (CNC) programming language, such as G-code.

System 400 comprises at least one positioning unit 415. The at least one positioning unit 415 may be configured to control a position and/or orientation of other aspects of system 400. For example, the at least one positioning unit 415 may control a translation in Cartesian X, Y, and/or Z planes. The at least one positioning unit 415 may control a rotation about an axis of rotation. The at least one positioning unit 415 may use any other co-ordinate system, as may be required or appropriate. The at least one positioning system 415 may be in operative communication with the at least one processor 410, positioning other units of system 400 in accordance with the assembly data. According to an example, there may be one “central” positioning unit which controls positioning of all other units of the system. Alternatively, according to an example, each unit of the system may be provided with its own positioning unit.

System 400 may comprise at least one pedestal 402. Pedestal 402 may be configured to receive substrate 401. Pedestal 402 may be a moveable pedestal in operative communication with the at least one positioning unit 415. Pedestal 402 may be moveable in X, Y and/or Z directions and/or may be able to tilt with some angle. Pedestal 402 may comprise thermal control, for example at least one of an embedded heating unit and/or cooling fan.

Pedestal 402 may be in operative communication with at least one flipper 403 for rotating the substrate. Alternatively, or complementarily, flipper 403 may be in operative communication with the at least one positioning system 415. Flipper 403 may allow a second side of substrate 401 to have a PWA manufactured thereupon. According to embodiments, when the second side of substrate 401 is to be dispensed upon and/or soldered, the first already processed side may be placed in a jig such that, when flipped, the already assembled and/or soldered components do not touch the at least one pedestal 402.

System 400 also comprises a plurality of dispensing units 420. The plurality of dispensing units 420 may be of any type such as, but not limited to: extruders, ink jets, and/or print heads. The plurality of dispensing units 420 may be configured to dispense at least one of conductive ink, dielectric ink, silver, solder paste, and/or plasma.

Conductive ink may comprise solderable metal or alloys as mentioned in IPC-AJ-820A, Table 6-1, preferably copper and/or nickel. Conducive ink may comprise a metal-organic decomposition (MOD) ink. Curing of conductive ink depends on the formulation. Conductive ink may be cured by at least one of sintering, thermal decomposition, or thermal bonding/coupling.

Dielectric ink may comprise non-electrically conductive material with predefined dielectric properties, Young's Modulus (storage and loss), glass transition temperature (Tg), coefficient of thermal expansion (CTE) and organic solder preservative compatibility. Curing of dielectric ink depends on the formulation. Dielectric ink may be cured by ultraviolet radiation.

Solder paste may comprise lead. Alternatively, solder paste may not comprise lead. Solder paste may be based on SnPb and/or SnAgCu metallurgies.

The plurality of dispensing units 420 may be configured to dispense vertically. The plurality of dispensing units 420 may be configured as an end effector of system 400 for jetting at any predefined angle on any curved surface. Alternatively, or complementarily, the plurality of dispensing units 420 may be configured to dispense at any predefined angle on any curved surface. The plurality of dispensing units 420 may be configured to dispense at any dynamically changing angle. The plurality of dispensing units 420 may be in operative communication with at least one of the at least one processor 410 and/or the at least one positioning unit 415. The plurality of dispensing units 420 may be configured to dispense according to the assembly data.

System 400 also comprises at least one energy source 430. The at least one energy source 430 may be a heating unit, and/or may be one of: convection based; infrared radiation based; or laser based. The at least one energy source 430 may comprise an ultraviolet radiation energy source. The at least one energy source 430 may be configured to perform any of: curing, plasma treatment, and/or solder material reflow. The at least one energy source 430 may be configured to perform sintering and/or thermal decomposition. The at least one energy source 430 may comprise a reflow oven.

System 400 may comprise an atmosphere 440. Atmosphere 440 may be controlled by the at least one processor 410. System 400 may be capable of gas purging. Gas purging may comprise generating a vacuum. Atmosphere 440 may comprise such a vacuum. Gas purging may comprise purging oxygen from system 400. Gas purging may comprise generating an inert atmosphere comprising an inert gas or mixture of inert gases. Atmosphere 440 may comprise a gas, or mixture of gases, other than oxygen. Atmosphere 440 may comprise a gas or mixture of gases suitable for at least one of: creating a surface reducing atmosphere, and/or creating an inert atmosphere. Atmosphere 440 may be generated, at least in part, by the at least one energy source 430.

System 400 also comprises at least one pick and place (P&P) unit 460. The at least one P&P unit 460 may be provided integrally as part of system 400, or as part of a separate unit within a cluster constituting system 400. The at least one P&P unit 460 may comprise an appropriate number of feeders for surface mount technology (SMT) components and/or solder material preforms. The at least one P&P unit 460 may be any of: a tray loading type; a reel loading type; or a bulk loading type. The at least one P&P unit 460 may be in operative communication with the at least one processor 410 and may pick and place in accordance with the assembly data. The at least one P&P unit 460 may be in operative communication with the at least one positioning unit 415.

According to embodiments, the at least one positioning unit 415 is configured to control a positioning and orientation of at least one of: the substrate 401; one or more dispensing units of the plurality of dispensing units 420; the at least one energy source 430; and/or the at least one P&P unit 460.

According to embodiments, system 400 may comprise at least one fume chamber.

According to embodiments, system 400 may comprise at least one testing unit 480 for testing an assembled, or part-assembled, PWA. The at least one testing unit 480 may comprise at least one automatic optical inspection (AOI) unit. The at least one AOI unit may comprise backlight illumination, which may be particularly useful in inspecting transparent or partially transparent inks, such as dielectric inks, dispensed on/as part of the substrate 401. Automatic Optical Inspection can monitor the quality of the following processing features: each singular layer of the bare board which is a combination of conductive ink and dielectric ink accordingly; solder paste topography on top of the cured conductive ink e.g. on top of formed copper pads; and/or component placement before and/or after reflow soldering. In fact, this universal AOI is a combination of inner and outer layer PCB AOI, SPI (Solder Paste Inspection) and SMT AOI.

According to embodiments, system 400 may comprise at least one of: a failure modes and effects analysis (FMEA) module; and/or a statistical process control (SPC) module. These and/or additional modules may be comprised in processor 410.

In operation, and according to embodiments, system 400 may dispense at least a portion of ink from one or more of the plurality of dispensing units 420. The plurality of dispensing units 420 may dispense ink in multiple passes. For example, the plurality of dispensing units 420 may dispense a first layer of ink, followed by a second layer of ink. The inks dispensed in different passes may be the same or different, or different inks may be dispensed concurrently in a single pass.

In operation, and according to embodiments, solder material is deposited on at least a portion of dispensed ink. Solder material may be deposited in the form of solder paste dispensed from one or more of the plurality of dispensing units 420. Alternatively, solder material may be deposited in the form of a solder material preform, picked and placed by the at least one P&P unit 460. The solder material preform may have a form conformal with at least a portion of dispensed ink. Some sections of substrate 401 may have solder material deposited as solder paste, and other sections may have solder material deposited as solder material preforms, as may be required or appropriate. Solder material, either as solder paste or solder material preform, may be a lead-based solder material or a lead-free solder material.

In operation, and according to embodiments, the at least one energy source 430 may be configured to couple the deposited solder material and the dispensed ink, forming an intermetallic compound therebetween.

In operation, and according to embodiments, dispensed ink may be cured or left uncured prior to deposition of solder material. Dispensed ink may be cured by the at least one energy source 430 prior to deposition of solder material. Dispensed ink, in particular dispensed conductive ink, may be cured by sintering. Dispensed ink, in particular MOD ink, may be cured by thermal decomposition. Dispensed ink, in particular dispensed dielectric ink, may be cured by ultraviolet (UV) radiation. Dispensed ink may be considered cured by the action of the at least one energy source 430 following deposition of solder material, e.g. by forming an intermetallic compound.

In operation, and according to embodiments, the plurality of dispensing units may be configured to dispense a first conductive ink comprising copper, followed by a second conductive ink comprising nickel on top of the dispensed first conductive ink comprising copper. The at least one energy source may then be configured to couple the first and the second dispensed conductive inks to form a “nickel over copper” intermetallic compound therebetween. Solder material may then be deposited on at least a portion of the nickel over copper intermetallic compound.

In operation, and according to embodiments, the at least one P&P unit 460 is configured to pick and place one or more components on deposited solder material. The components may be of an SMT type. The at least one energy source 430 may be configured to perform reflow soldering of the deposited solder material and the one or more placed components, forming an intermetallic compound therebetween.

According to embodiments, system 400 may be configured in at least three different configurations to produce PWAs on a substrate 401.

According to at least all three configurations, system 400 comprises: at least one processor 410, configured to receive assembly data; at least one positioning system 415; a plurality of dispensing units 420; at least one energy source 430; and at least one pick and place “P&P” unit 460. According to at least all three configurations, the at least one positioning system 415 is configured to control a position and orientation of at least one of: the substrate 401; one or more dispensing units of the plurality of dispensing units 420; the at least one energy source 430; and/or the at least one P&P unit 460.

According to at least a first configuration, at least one of the plurality of dispensing units 420 is configured to dispense a conductive ink, according to the assembly data. According to at least the first configuration, at least one energy source 430 is configured to cure the dispensed conductive ink, and the at least one energy source 430 is also configured to reduce, by plasma treatment, the cured conductive ink. According to at least the first configuration, at least one of the plurality of dispensing units 420, or the at least one P&P unit 460, is configured to deposit a solder material on top of at least a portion of the reduced conductive ink. According to at least the first configuration, the at least one P&P unit 460 is configured to pick and place one or more components on the deposited solder material, according to the assembly data. According to at least the first configuration, the at least one energy source 430 is configured to perform reflow soldering of the deposited solder material, the one or more placed components, and the reduced conductive ink, forming an intermetallic compound therebetween.

According to at least a second configuration, at least one of the plurality of dispensing units 420 is configured to dispense a conductive ink “CI”, according to the assembly data. According to at least the second configuration, at least one of the plurality of dispensing units 420 is configured to dispense a thin film of silver onto the dispensed conductive ink, according to the assembly data. According to at least the second configuration, the at least one energy source 430 is configured to co-cure the dispensed conductive ink and the dispensed silver, forming a silver over CI finish. According to at least the second configuration, at least one of the plurality of dispensing units 420, or the at least one P&P unit 460, is configured to deposit a solder material on top of at least a portion of the silver over CI finish. According to at least the second configuration, the at least one P&P unit 460 is configured to pick and place one or more components on the deposited solder material, according to the assembly data. According to at least the second configuration, the at least one energy source 430 is configured to perform reflow soldering of the deposited solder material, the one or more placed components, and the silver over CI finish, forming an intermetallic compound therebetween.

According to at least a third configuration, at least one of the plurality of dispensing units 420 is configured to dispense a conductive ink, according to the assembly data. According to at least the third configuration, at least one of the plurality of dispensing units 420, or the at least one P&P unit 460, is configured to deposit a solder material on top of at least a portion of dispensed conductive ink soon thereafter, wherein the dispensed conductive ink has been at most partially cured prior to depositing said solder material soon thereafter. According to at least the third configuration, the at least one P&P unit 460 is configured to pick and place one or more components on the deposited solder material, according to the assembly data. According to at least the third configuration, the at least one energy source 430 is configured to perform reflow soldering of the deposited solder material, the one or more placed components, and the dispensed conductive ink, forming an intermetallic compound therebetween.

According to embodiments of the present invention, PWAs fabricated by system 400 may be soldered according to at least any of the three reflow profiles mentioned in IPC-7095D, Table 7-7, or equivalent. In any case, minimum soldering temperature is required to ensure metallurgical bonding e.g. the formation of intermetallic compounds of some of the base metals and one or more constituents of the solder alloy as per IPC-7530A, paragraph 1.2 or equivalent. It is not necessary to use reflow soldering as a method of heating the solder material, for example a laser or other methods may be used.

There are thus provided at least three methods for manufacturing PWAs, according to embodiments of the present invention.

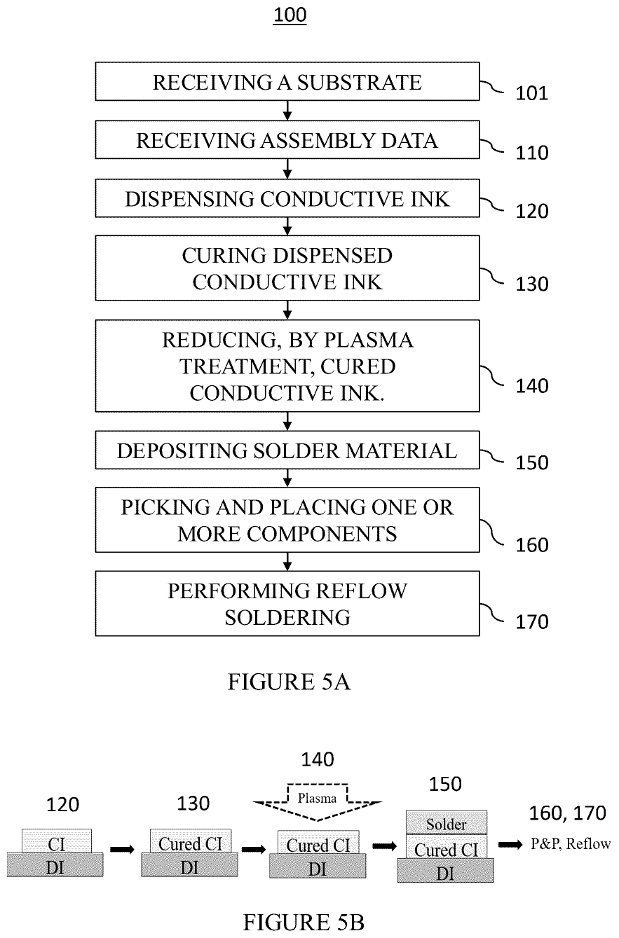

With reference to FIG. 5, according to a first method embodiment (100) corresponding to at least the first system configuration, a printed wiring assembly (PWA) is manufactured on a substrate. The substrate may be received (101). Receiving the substrate may comprise manufacturing/fabricating a substrate in a machine according to system embodiments of the present invention using methods well known in the art.

Method 100 further comprises receiving (110) assembly data. The assembly data may comprise a Bill of Material (BoM) which may comprise a list of components. The assembly data may also comprise machine readable code in a computer numerical control (CNC) programming language, such as G-code.

Method 100 further comprises dispensing (120), onto the substrate, and in accordance with the assembly data, a conductive ink. The conductive ink may comprise at least one of copper and/or nickel. The conductive ink may comprise a metal-organic decomposition (MOD) ink.

Dispensing a conductive ink may comprise: dispensing a first conductive ink comprising copper; and dispensing a second conductive ink comprising nickel on top of the dispensed first conductive ink comprising copper.

Method 100 further comprises curing (130) the dispensed conductive ink. Curing the dispensed conductive ink may comprise sintering and/or thermal decomposition of the dispensed conductive ink.

Curing the conductive ink may comprise coupling, by heating, a first conductive ink comprising copper and a second conductive ink comprising nickel, forming a nickel over copper intermetallic compound therebetween.

Method 100 further comprises reducing (140), by plasma treatment, the cured conductive ink. The plasma treatment may be effective to remove oxides and/or other surface contaminants from the surface of the cured conductive ink. The plasma treatment may comprise at least one of: hydrogen plasma treatment, oxygen with nitrogen plasma treatment, or oxygen with argon plasma treatment.

According to some embodiments, cured conductive ink is left uncoated, in contrast to some prior art approaches. For example, according to some embodiments of the invention, plasma treatment may be sufficient to remove oxides and/or other surface contaminants from the surface of the cured conductive ink, and preventative techniques, such as coating conductive ink tracks with a polymer, are not required. In using plasma treatment of the cured conductive ink, as opposed to coating, embodiments of the invention avoid the need to solder through any such applied coating. In particular, embodiments of the invention may not coat cured (or partially cured) conductive ink with a for example halo-hydrocarbon polymer, thereby avoiding soldering through such coating to form an intermetallic compound with the underlying, coated, conductive ink. Soldering through such a coating may decrease an effectiveness of the intermetallic compound formed. For example, soldering through a polymer coating, such as a halo-hydrocarbon polymer, may leave regions or segregations of the coating within the intermetallic compound, which may increase a resistance of the connection or to reduce the reliability of the soldered joint.

Method 100 further comprises depositing (150) a solder material on top of at least a portion of the reduced conductive ink. Depositing a solder material may comprise dispensing a solder paste. Depositing a solder material may comprise picking and placing a solder material preform. A solder material preform may have a form conformal with at least a portion of dispensed ink.

Method 100 further comprises picking and placing (160), in accordance with the assembly data, one or more components on the deposited solder material. The picking and placing may be performed by a pick and place unit. The one or more components may comprise surface mount technology.

Method 100 further comprises performing reflow soldering (170), by heating, of the deposited solder material, the one or more placed components, and the reduced conductive ink, forming an intermetallic compound therebetween. Performing reflow soldering may comprise any of the three reflow profiles as mentioned in IPC-7095D, Table 7-7, or equivalent.

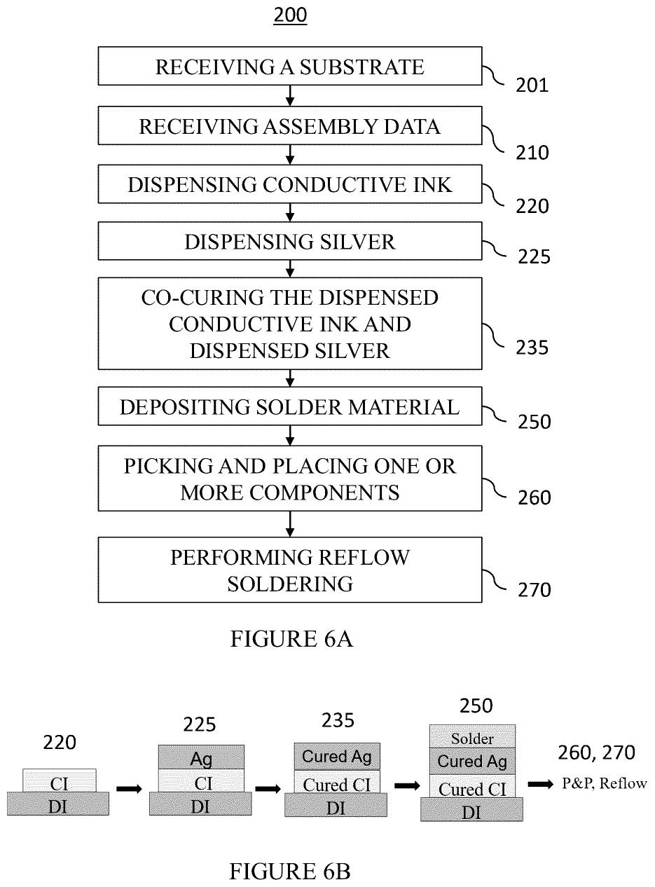

With reference to FIG. 6, according to a second method embodiment (200) corresponding to at least the second system configuration, there is provided a method for printed wiring assembly on a substrate. As with method 100, the substrate may be received (201). Receiving the substrate may comprise manufacturing/fabricating a substrate in a machine according to system embodiments of the present invention using methods well known in the art.

Method 200 comprises receiving (210) assembly data. As with method 100, the assembly data may comprise a Bill of Material (BoM) which may comprise a list of components. The assembly data may also comprise machine readable code in a computer numerical control (CNC) programming language, such as G-code.

Method 200 further comprises dispensing (220), onto a substrate, and in accordance with the assembly data, a conductive ink “CI”. As with method 100, The conductive ink may comprise at least one of copper and/or nickel. The conductive ink may comprise a metal-organic decomposition (MOD) ink.

Method 200 further comprises dispensing (225), onto the dispensed conductive ink, and in accordance with the assembly data, a thin film of silver. The silver may be dispensed at a thickness conforming with IPC-4553A or any other standard as may be developed in the future. The minimum thickness of dispensed silver may be 0.12 μm and the maximum thickness of dispensed silver may be 0.4 μm. The silver may be dispensed at a thickness that ranges from 0.2 μm to 0.3 μm.

Method 200 further comprises co-curing (235) the dispensed conductive ink and dispensed silver, forming a silver over CI finish. Co-curing the dispensed conductive ink and the dispensed silver may comprise at least one of sintering, thermal decomposition, or thermal bonding/coupling of the dispensed conductive ink and the dispensed silver, at the same time. Alternatively, as opposed to co-curing, the dispensed conductive ink and dispensed silver may be cured one after the other. The silver over CI finish may be effective to achieve a similar or improved finish as would be achieved by using immersion silver according to methods known in the art. The silver over CI finish can be achieved without the need for chemical baths and electroplating processes.

Method 200 further comprises depositing (250) a solder material on top of at least a portion of the silver over CI finish. As with method 100, Depositing a solder material may comprise dispensing a solder paste. Depositing a solder material may comprise picking and placing a solder material preform. A solder material preform may have a form conformal with at least a portion of the silver over CI finish.

Method 200 further comprises picking and placing (260), in accordance with the assembly data, one or more components on the deposited solder material. As with method 100, The picking and placing may be performed by a pick and place unit. The one or more components may comprise surface mount technology.

Method 200 further comprises performing reflow soldering (270), by heating, of the deposited solder material, the one or more placed components, and the silver over CI finish, forming an intermetallic compound therebetween. As with method 100, performing reflow soldering may comprise any of the three reflow profiles as mentioned in IPC-7095D, Table 7-7, or equivalent.

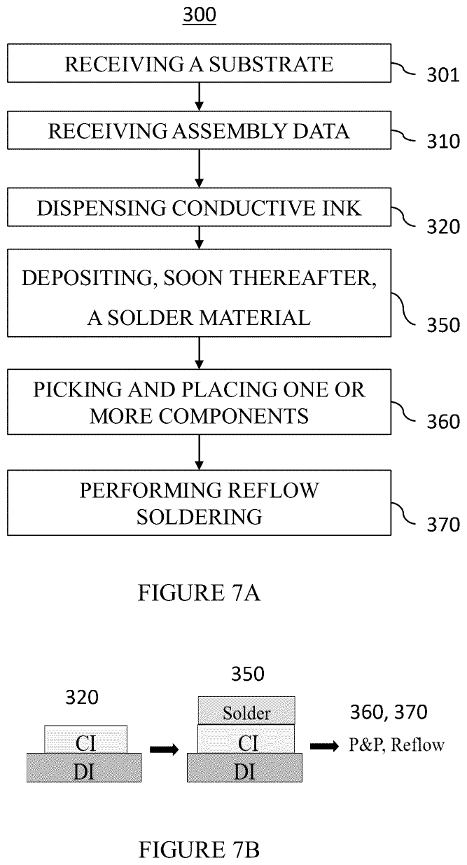

With reference to FIG. 7, according to a third method embodiment (300) corresponding to at least the third system configuration, there is provided a method for printed wiring assembly on a substrate. As with methods 100 and 200, the substrate may be received (301). Receiving the substrate may comprise manufacturing/fabricating a substrate in a machine according to system embodiments of the present invention using methods well known in the art.

Method 300 comprises receiving (310) assembly data. As with methods 100 and 200, the assembly data may comprise a Bill of Material (BoM) which may comprise a list of components. The assembly data may also comprise machine readable code in a computer numerical control (CNC) programming language, such as G-code.

Method 300 further comprises dispensing (320), onto a substrate, and in accordance with the assembly data, a conductive ink. The conductive ink may comprise at least one of copper and/or nickel. The conductive ink may comprise a metal-organic decomposition (MOD) ink.

Method 300 further comprises depositing (350), soon thereafter, a solder material on top of at least a portion of the dispensed conductive ink, wherein the dispensed conductive ink has been at most partially cured prior to depositing said solder material soon thereafter.

Soon thereafter may comprise depositing solder material immediately, or almost immediately. Soon thereafter may comprise a time scale on the order of seconds, minutes, or hours. Soon thereafter may comprise 0-60 seconds, 0-60 minutes, or 0-24 hours. Soon thereafter may comprise any period of time less than one day after dispensing the conductive ink. Soon thereafter may comprise depositing solder material “back-to-back” with the dispensed conductive ink. Soon thereafter may comprise depositing solder paste “wet-on-wet” with the dispensed conductive ink, for example depositing solder paste that is not entirely solid on conductive ink that is not entirely solid.

Soon thereafter may comprise dispensing one or more planar layers of specific geometry/topography of conductive ink, forming conductive traces/pads in accordance with the assembly data across an effective area of the substrate prior to depositing the solder material. Alternatively, soon thereafter may comprise depositing solder material as and when sections of conductive traces/pads are completed. In other words, solder material can be deposited after completing all conductive traces/pads, or after completing a particular conductive trace/pad.

Preferably, soon thereafter comprises any period of time that is effective to prevent or reduce the likelihood of the dispensed conductive ink from oxidizing.

At most partially cured may comprise incidental curing by natural drying of the conductive ink. At most partially cured may comprise taking no deliberate steps to cure the conductive ink, for example by forgoing sintering.

Method 300 further comprises picking and placing, in accordance with the assembly data, one or more components on the deposited solder material. The picking and placing may be performed by a pick and place unit. The one or more components may comprise surface mount technology.

Method 300 further comprises performing reflow soldering (370), by heating, of the deposited solder material, the one or more placed components, and the dispensed conductive ink, forming an intermetallic compound therebetween. As with methods 100 and 200, performing reflow soldering may comprise any of the three reflow profiles as mentioned in IPC-7095D, Table 7-7, or equivalent.

In at least each method (100, 200, 300), due to the unique processing sequences, well-known and reliable SnxCuy (Tin-Copper) or SnxNiy (Tin-Nickel) IMCs are created exactly per IPC standards. From a commercial point of view, this means that the AME methodology is ready for expansion into the PWA world providing virtually endless possibilities and means that even in a basic configuration a machine, system, or cluster according to embodiments of the invention will be scalable.

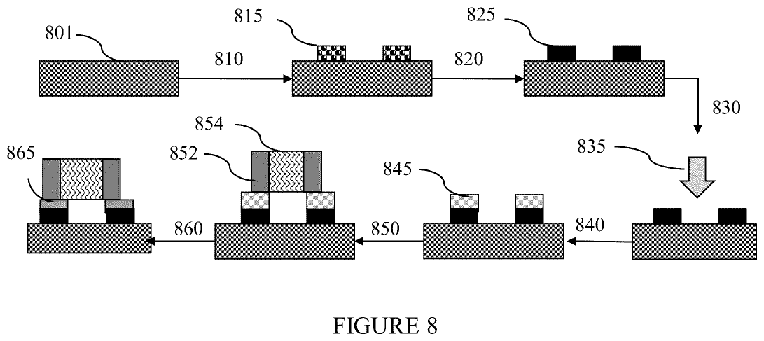

Referring now to FIG. 8, a PWA may be assembled in the following way, according to embodiments of the invention. As an initial step, a substrate 801 is received. Substrate 801 may be, for example, a printed circuit board. Substrate 801 may comprise one or more dielectric inks. Substrate 801 may be manufactured by a system according to embodiments of the invention: for example, substrate 801 may be manufactured by dispensing, from one or more of the plurality of dispensing units, one or more dielectric inks. Substrate 801 may comprise dyes, or dyed dielectric inks, for example at least a part of substrate 801 may be dyed green in colour.

In Step 810, conductive ink 815 is dispensed onto substrate 801. Conductive ink 801 may be, for example, one of copper, nickel and/or silver.

Step 810 may be repeated, such that other sections of substrate 801 have a same or different conductive ink dispensed on at least a different portion of substrate 801. Alternatively, or complementarily, Step 810 may be repeated in different passes, such that successive layers of the same or different conductive ink are dispensed on previously dispensed layers of conductive ink 815.

As an optional Step 820, dispensed conductive ink 815 may be cured. Dispensed conductive ink 815 may be cured, for example, by sintering, thermal decomposition, or thermal bonding/coupling. Dispensed conductive ink 815 which has been cured becomes cured dispensed conductive ink 825.

As an optional Step 830, cured dispensed conductive ink 825 may be subjected to plasma treatment 835. Plasma treatment 835 may be effective to remove surface contaminants and or/oxidation from cured dispensed conductive ink 825.

Optional Step 820 and Step 830 may not be required if solder material is to be deposited almost immediately on dispensed conductive ink. Solder material may be deposited atop dispensed conductive ink whether cured or uncured.

In Step 840, solder material 845 is deposited over at least a portion of dispensed (cured) conductive ink 815 (825). According to embodiments of the invention, solder material 845 may be deposited in the form of solder paste, dispensed from one of the plurality of dispensing units of the system. Alternatively, and according to embodiments of the invention, solder material 845 may be deposited in the form of a solder material preform, picked, and placed by a P&P unit of the system.

In Step 850, at least one component 854 is picked and placed atop the deposited solder material. Component 854 may have one or more conducting legs/terminations 852, or any other means of contacting and/or interfacing as will be known in the art.

In Step 860, reflow soldering is performed, for example by an energy source. The reflow soldering is of the deposited solder material 845, the one or more placed components 845, and the dispensed conductive ink 815/825, forming an intermetallic compound 865 therebetween.

In subsequent optional steps the assembled PWA may be inspected and/or tested by means known in the art.

The basic system and/or machines may be operated by only one qualified person responsible for the whole fabrication process. The first step of the fabrication process may comprise programming and the final step may comprise an optical inspection of the last soldered side of the substrate. The same one qualified person may also be responsible for calibration and maintenance of the basic system and/or machines as well.

The system may be equipped with additional features such as, but not limited to:
vacuum chamber for vapor phase soldering, surface treatment, and/or drying; corona activation; Selective Soldering; more dispensing units configured to dispense embedded capacitors and/or resistors, SMT or glob top adhesive, underfill, and/or conformal coating; electrical test capability such as Flying Probe technique; X-ray, CT, or any other non-destructive testing (NDT) method. Any combination of these features is possible.

In such cases the last processing step is customer dependent. For instance, conformal coating can be the last processing step if the system is equipped with an appropriate module.

Advantageously, some embodiments of the present invention may be customized with any extra processing steps such as, but not limited to: Solder ball or solder bump dispensing unit; Wire bond (ball bonding/wedge bonding) unit; Conductive adhesive dispensing; ACF (Anisotropic Conductive Film) placement unit; Under fill dispensing unit; Dam and fill dispensing; Glop top dispensing; Conformal coating unit; Metrological and inspection techniques based on non-destructive testing (NDT) such as, but not limited to: X-Ray, mechanical dimension optical inspection, flying probe electrical test etc.; Marking unit base on ink (additive) or laser (subtractive) approaches; Functional plasma treatment of above mentioned processes such as argon, oxygen, forming Gas etc.; and Grinder unit for planarization and polishing CI and DI cured layers.

Further advantageously, in accordance with some embodiments of the present invention, the aforementioned customization may be implemented for component level assembly and/or Heterogeneous Integration (HI) approach.

It is to be appreciated that a number of different system and method embodiments have been presented and that features and/or steps of one embodiment may be combined with another embodiment in any working combination.

As will be appreciated by one skilled in the art, aspects of the present invention may be embodied as a system, method, or computer program product. Accordingly, some aspects of the present invention may take the form of an entirely hardware embodiment, an entirely software embodiment (including firmware, resident software, micro-code, etc.) or an embodiment combining software and hardware aspects that may all generally be referred to herein as a “circuit,” “module” or “system.” Furthermore, aspects of the present invention may take the form of a computer program product embodied in one or more computer readable medium(s) having computer readable program code embodied thereon.

Any combination of one or more computer readable medium(s) may be utilized. The computer readable medium may be a computer readable signal medium or a computer readable storage medium. A computer readable storage medium may be, for example, but not limited to, an electronic, magnetic, optical, electromagnetic, infrared, or semiconductor system, apparatus, or device, or any suitable combination of the foregoing. More specific examples (a non-exhaustive list) of the computer readable storage medium would include the following: an electrical connection having one or more wires, a portable computer diskette, a hard disk, a random access memory (RAM), a read-only memory (ROM), an erasable programmable read-only memory (EPROM or Flash memory), an optical fiber, a portable compact disc read-only memory (CD-ROM), an optical storage device, a magnetic storage device, or any suitable combination of the foregoing. In the context of this document, a computer readable storage medium may be any tangible medium that can contain or store a program for use by or in connection with an instruction execution system, apparatus, or device.

A computer readable signal medium may include a propagated data signal with computer readable program code embodied therein, for example, in base band or as part of a carrier wave. Such a propagated signal may take any of a variety of forms, including, but not limited to, electro-magnetic, optical, or any suitable combination thereof. A computer readable signal medium may be any computer readable medium that is not a computer readable storage medium and that can communicate, propagate, or transport a program for use by or in connection with an instruction execution system, apparatus, or device.

Program code embodied on a computer readable medium may be transmitted using any appropriate medium, including but not limited to wireless, wire-line, optical fiber cable, RF, etc., or any suitable combination of the foregoing. Computer program code for carrying out operations for aspects of the present invention may be written in any combination of one or more programming languages, including an object-oriented programming language such as Java, Smalltalk, C++, or the like and conventional procedural programming languages, such as the “C” programming language or similar programming languages. The program code may execute entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider).

Some aspects of the present invention are described above with reference to flowchart illustrations and/or portion diagrams of methods, apparatus (systems) and computer program products according to some embodiments of the invention. It will be understood that each portion of the flowchart illustrations and/or portion diagrams, and combinations of portions in the flowchart illustrations and/or portion diagrams, can be implemented by computer program instructions. These computer program instructions may be provided to a processor of a general-purpose computer, special purpose computer, or other programmable data processing apparatus to produce a machine, such that the instructions, which execute via the processor of the computer or other programmable data processing apparatus, create means for implementing the functions/acts specified in the flowchart and/or portion diagram portion or portions.

These computer program instructions may also be stored in a computer readable medium that can direct a computer, other programmable data processing apparatus, or other devices to function in a particular manner, such that the instructions stored in the computer readable medium produce an article of manufacture including instructions which implement the function/act specified in the flowchart and/or portion diagram portion or portions.

The computer program instructions may also be loaded onto a computer, other programmable data processing apparatus, or other devices to cause a series of operational steps to be performed on the computer, other programmable apparatus or other devices to produce a computer implemented process such that the instructions which execute on the computer or other programmable apparatus provide processes for implementing the functions/acts specified in the flowchart and/or portion diagram portion or portions.

The aforementioned flowchart and diagrams illustrate the architecture, functionality, and operation of possible implementations of systems, methods, and computer program products according to various embodiments of the present invention. In this regard, each portion in the flowchart or portion diagrams may represent a module, segment, or portion of code, which comprises one or more executable instructions for implementing the specified logical function(s). It should also be noted that, in some alternative implementations, the functions noted in the portion may occur out of the order noted in the figures. For example, two portions shown in succession may, in fact, be executed substantially concurrently, or the portions may sometimes be executed in the reverse order, depending upon the functionality involved. It will also be noted that each portion of the portion diagrams and/or flowchart illustration, and combinations of portions in the portion diagrams and/or flowchart illustration, can be implemented by special purpose hardware-based systems that perform the specified functions or acts, or combinations of special purpose hardware and computer instructions.

In the above description, an embodiment is an example or implementation of the inventions. The various appearances of “one embodiment,” “an embodiment” or “some embodiments” do not necessarily all refer to the same embodiments.

Although various features of the invention may be described in the context of a single embodiment, the features may also be provided separately or in any suitable combination. Conversely, although the invention may be described herein in the context of separate embodiments for clarity, the invention may also be implemented in a single embodiment.

Reference in the specification to “some embodiments”, “an embodiment”, “one embodiment” or “other embodiments” means that a particular feature, structure, or characteristic described in connection with the embodiments is included in at least some embodiments, but not necessarily all embodiments, of the inventions.

It is to be understood that the phraseology and terminology employed herein is not to be construed as limiting and are for descriptive purpose only. The principles and uses of the teachings of the present invention may be better understood with reference to the accompanying description, figures, and examples.

It is to be understood that the details set forth herein do not construe a limitation to an application of the invention. Furthermore, it is to be understood that the invention can be carried out or practiced in various ways and that the invention can be implemented in embodiments other than the ones outlined in the description above.

It is to be understood that the terms “including”, “comprising”, “consisting” and grammatical variants thereof do not preclude the addition of one or more components, features, steps, or integers or groups thereof and that the terms are to be construed as specifying components, features, steps, or integers. If the specification or claims refer to “an additional” element, that does not preclude there being more than one of the additional element. It is to be understood that, where the claims or specification refer to “a” or “an” element, such reference is not to be construed that there is only one of that element. It is to be understood that where the specification states that a component, feature, structure, or characteristic “may”, “might”, “can” or “could” be included, that particular component, feature, structure, or characteristic is not required to be included. Where applicable, although state diagrams, flow diagrams or both may be used to describe embodiments, the invention is not limited to those diagrams or to the corresponding descriptions. For example, flow need not move through each illustrated box or state, or in exactly the same order as illustrated and described. Methods of the present invention may be implemented by performing or completing manually, automatically, or a combination thereof, selected steps or tasks.

The term “method” may refer to manners, means, techniques and procedures for accomplishing a given task including, but not limited to, those manners, means, techniques and procedures either known to, or readily developed from known manners, means, techniques and procedures by practitioners of the art to which the invention belongs. The descriptions, examples, methods and materials presented in the claims and the specification are not to be construed as limiting but rather as illustrative only. Meanings of technical and scientific terms used herein are to be commonly understood as by one of ordinary skill in the art to which the invention belongs, unless otherwise defined.

The present invention may be implemented in the testing or practice with methods and materials equivalent or similar to those described herein. Any publications, including patents, patent applications and articles, referenced or mentioned in this specification are herein incorporated in their entirety into the specification, to the same extent as if each individual publication was specifically and individually indicated to be incorporated herein. In addition, citation or identification of any reference in the description of some embodiments of the invention shall not be construed as an admission that such reference is available as prior art to the present invention.

While the invention has been described with respect to a limited number of embodiments, these should not be construed as limitations on the scope of the invention, but rather as exemplifications of some of the preferred embodiments. Other possible variations, modifications, and applications are also within the scope of the invention. Accordingly, the scope of the invention should not be limited by what has thus far been described, but by the appended claims and their legal equivalents.

1. A method of manufacturing a printed wiring assembly (“PWA”) on a substrate, said method comprising:
receiving assembly data associated with said PWA;
dispensing, onto said substrate, and in accordance with the assembly data, a conductive ink;
curing the dispensed conductive ink;
reducing, by plasma treatment, the cured conductive ink;
depositing a solder material on top of at least a portion of the reduced conductive ink;
picking and placing, in accordance with the assembly data, one or more components on the deposited solder material; and
performing reflow soldering, by heating, of the deposited solder material, the one or more placed components, and the reduced conductive ink, forming an intermetallic compound therebetween.

2. The method of claim 1, wherein the plasma treatment comprises hydrogen plasma or any other mixture of gasses which can successfully reduce the surface of the conductive ink.

3. A method of manufacturing a printed wiring assembly “PWA” on a substrate, said method comprising:
receiving assembly data associated with said PWA;
dispensing, onto said substrate, and in accordance with the assembly data, a conductive ink “CI”;
dispensing, onto the dispensed conductive ink, and in accordance with the assembly data, a thin film of silver;
co-curing the dispensed conductive ink and dispensed silver, forming a silver over CI finish;
depositing a solder material on top of at least a portion of the silver over CI finish;
picking and placing, in accordance with the assembly data, one or more components on the deposited solder material; and
performing reflow soldering, by heating, of the deposited solder material, the one or more placed components, and the silver over CI finish, forming an intermetallic compound therebetween.

4. The method of claim 3, wherein the thickness of dispensed silver is between 0.12 μm and 0.4 μm.

5. The method of claim 4, wherein co-curing the dispensed conductive ink and the dispensed silver comprises at least one of sintering, thermal decomposition, or thermal coupling of the dispensed conductive ink and the dispensed silver, at the same time.

6. The method of claim 1, wherein curing the dispensed conductive ink comprises at least one of: sintering, thermal decomposition, or thermal coupling of the dispensed conductive ink.

7. The method of claim 1, wherein the conductive ink comprises at least one of: copper or nickel.

8. The method of claim 1, wherein performing reflow soldering comprises any of the three reflow profiles as mentioned in IPC-7095D, Table 7-7, or equivalent.

9. The method of claim 1, wherein dispensing a conductive ink comprises: dispensing a first conductive ink comprising copper;
dispensing a second conductive ink comprising nickel on top of the dispensed first conductive ink comprising copper; and
coupling, by heating, the first conductive ink comprising copper and the second conductive ink comprising nickel, forming a nickel over copper intermetallic compound therebetween.

10. A system for manufacturing a printed wiring assembly “PWA” on a substrate, said system comprising:
at least one processor, configured to receive assembly data associated with said PWA;
at least one positioning system;
a plurality of dispensing units;
at least one energy source; and
at least one pick and place “P&P” unit,
wherein at least one of the plurality of dispensing units is configured to dispense a conductive ink according to the assembly data,
wherein the at least one energy source is configured to cure the dispensed conductive ink, and wherein the at least one energy source is configured to reduce, by plasma treatment, the cured conductive ink,
wherein at least one of the plurality of dispensing units, or the at least one P&P unit, is configured to deposit a solder material on top of at least a portion of the reduced conductive ink,
wherein the at least one P&P unit is configured to pick and place one or more components on the deposited solder material, according to the assembly data,
wherein the at least one energy source is configured to perform reflow soldering of the deposited solder material, the one or more placed components, and the reduced conductive ink, forming an intermetallic compound therebetween, and
wherein the at least one positioning system is configured to control a position and orientation of at least one of: the substrate; one or more dispensing units of the plurality of dispensing units; the at least one energy source; and/or the at least one P&P unit.

11. The system of claim 10, wherein the conductive ink comprises at least one of copper or nickel.

12. The system of claim 10, wherein at least one of the plurality of dispensing units is capable of dispensing at at least one of: any predefined angle, and/or any dynamically changing angle.

13. The system of claim 10, wherein at least one of the plurality of dispensing units is configured to deposit solder material by dispensing solder paste.

14. The system of claim 10, wherein the at least one P&P unit is configured to deposit solder material by picking and placing a solder material preform on at least a portion of a dispensed conductive ink.

15. The system of claim 10, wherein the at least one P&P unit is any of: a tray loading type; a reel loading type; or a bulk loading type.

16. The system of claim 10, further comprising at least one flipper for rotating the substrate.

17. The system of claim 10, configured for gas purging.

18. The system of claim 17, comprising an atmosphere of gas, or mixture of gases, other than oxygen.

19. The system of claim 17, comprising a gas or mixture of gases suitable for at least one of: creating a surface reducing atmosphere, and/or creating an inert atmosphere.

20. The system of claim 10, further comprising at least one automatic optical inspection “AOI” unit.
